(19) United States
(12) Patent Application Publication
(10) Pub. No.: US 2009/0128167 A1
(43) Pub. Date: May 21, 2009

(54) METHOD FOR MEASURING AREA RESISTANCE OF MAGNETO-RESISTANCE EFFECT ELEMENT

(75) Inventors: Yusuke Hamada, Kawasaki (JP); Kenichi Kawai, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/263,284

(22) Filed: Oct. 31, 2008

(30) Foreign Application Priority Data
Nov. 19, 2007 (JP) 2007-298828

(51) Int. Cl. G01R 27/02

(52) U.S. Cl. 324/693

(57) ABSTRACT

A method for measuring an area resistance of a magneto-resistance effect element which includes an upper-barrier layer having a first sheet resistivity Rt, a barrier layer, and a lower-barrier layer having a second sheet resistivity Rb, includes a resistance measurement step, a sheet resistivity measurement step and a establishing step. The resistance measurement step is the step of measuring a resistance R of the magneto-resistance effect element by using predetermined terminals. The sheet resistivity measurement step measures the first sheet resistivity Rt and the second sheet resistivity Rb. The establishing step determines the area resistance RA of the magneto-resistance effect element using the first sheet resistivity Rt, the second sheet resistivity Rb, the resistance R and the intervals among the predetermined terminals.

### CROSS-REFERENCE TO RELATED APPLICATION

This application is based upon and claims the benefit of priority of prior Japanese Patent Application No. 2007-298828, filed on Nov. 19, 2007, the entire contents of which are incorporated herein by reference.

### BACKGROUND

1. Field

An aspect of the invention is related to a method for measuring the area resistance of a magneto-resistance effect element which includes an upper-barrier layer having a first sheet resistivity, a barrier layer, and a lower-barrier layer having a second sheet resistivity.

2. Description of the Related Art

A TMR element is mentioned as an example of a magneto-resistance effect element which includes an upper-barrier layer, a barrier layer, and a lower-barrier layer.

Regarding a TMR (Tunneling Magneto-Resistance) effect, a first report was made in 1975. Thereafter, it was reported in 1995 that a junction film employing aluminum oxide (AlO) for the barrier layer could attain a very large MR ratio equal to or greater than 10% at a room temperature. Thenceforth, research and development was accelerated toward a next-generation magnetic head for a hard disk drive, an MRAM (Magneto-resistive Random Access Memory), etc.

Further, it was indicated in 2004 that a very high magneto-resistance effect of 100-200% was attained in a tunneling magneto-resistance effect (TMR) film which employed magnesium oxide (MgO) for the barrier layer (S. Yuasa et al., “Giant room-temperature magnetoresistance in single-crystal Fe/MgO/Fe magnetic tunnel junctions”, Nature Materials, Vol. 3, pp. 868-871, December 2004, and S. S. P. Parkin et al., “Giant tunnelling magnetoresistance at room temperature with MgO (100) tunnel barriers”, Nature Materials, Vol. 3, pp. 862-871, December 2004). Thenceforth, the TMR film has been anticipated as the most hopeful technique for heightening the read output of magnetic heads for hard disk drives in the future, and the research and development of TMR films has been proceeding together with the application to the MRAM.

The characteristics of the TMR film are evaluated with the MR ratio mentioned before, and an RA value (to be detailed later), which is the area resistance of the magneto-resistance effect element. Accordingly, the measurement values (RA and MR ratio) need to be acquired with high precision to estimate the characteristics of the TMR film with high precision.

One technique for evaluating the RA and the MR ratio without working the TMR element itself is a CIPT (Current In-Plane Tunneling) method. The CIPT method is a method wherein probes (electrodes) located at very narrow intervals of several μm are directly pressed onto the TMR element so as to perform a four-terminal measurement, to measure the resistance R of the TMR film.

The resistance R is measured as a function of the RA (to be detailed later) of the TMR element, the sheet resistivity Rt (to be detailed later) of a layer above the barrier layer of the TMR element, the sheet resistivity Rb (to be detailed later) of a layer below the barrier layer of the TMR element, and the intervals a, b, c and d (to be detailed later) among the four probes. Accordingly, the resistance R of the TMR film is measured at a plurality of sorts of probe intervals, and the three variables Rt, Rb and RA are established by using the obtained measurement values, whereby these values can be obtained. Heretofore, the RA value has been obtained using this technique, and the characteristics of the TMR film have been evaluated.

The establishing in the prior art, however, has had the problem that, measurement precision is inferior, so only values of low reliability can be obtained. By way of example, σ/Average≈3% in the vicinity of RA=3 Ω·μm², and the measurement precision is inferior as compared with the dispersion of the RA value.

### SUMMARY

Accordingly, it is an object of the embodiments to provide a method for measuring the sheet resistance of a magneto-resistance effect element as can enhance a establishing precision, thereby to acquire a measurement value (RA value) of high precision.

According to an aspect of the invention, a method for measuring an area resistance of a magneto-resistance effect element which includes an upper-barrier layer having a first sheet resistivity Rt, a barrier layer, and a lower-barrier layer having a second sheet resistivity Rb, includes the steps of a resistance measurement step, a sheet resistivity measurement step and a establishing step. The resistance measurement step is the step of measuring a resistance resistance R of the magneto-resistance effect element by using predetermined terminals. The sheet resistivity measurement step is the step of measuring the first sheet resistivity Rt and the second sheet resistivity Rb. The establishing step is the step of establishing the area resistance RA of the magneto-resistance effect element by using the first sheet resistivity Rt, the second sheet resistivity Rb, the resistance R and the intervals among the predetermined terminals.

Additional objects and advantages of the invention will be set forth in part in the description which follows, and in part will be obvious from the description, or may be learned by practice of the invention. The object and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF DRAWINGS

The present invention will be explained with reference to the accompanying drawings.

FIG. 1 is a schematic view showing the film configuration of a magneto-resistance effect element according to an embodiment of the present invention;

FIG. 2 is a schematic view showing the film configuration of a TMR element for a CIPT measurement as is used in a measurement method according to an embodiment of the invention;

FIG. 3 is an explanatory view for explaining a method for measuring the sheet resistance of a magneto-resistance effect element, according to an embodiment of the invention;

FIG. 4 is a flow chart of a method for measuring the sheet resistance of a magneto-resistance effect element, according to an embodiment of the invention; and

FIG. 5 is a graph showing the continuous measurement results of the same sample based on the comparison between a measurement method in the prior art and a measurement method according to an embodiment of the invention.

### DETAILED DESCRIPTION OF THE PREFERRED EMBODIMENTS

Embodiments of the present invention will be described in detail below with reference to the accompanying drawings.

The embodiments of a method for measuring the sheet resistance of a magneto-resistance effect element, according to the invention will be described below by mentioning a TMR element as an example.

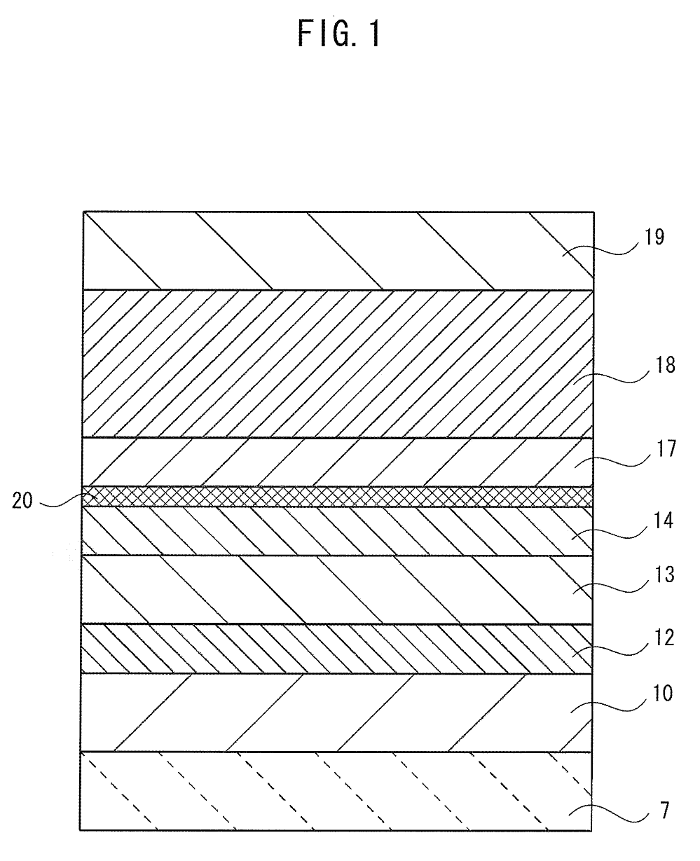

FIG. 1 is a schematic view showing the film configuration of a magneto-resistance effect element according to the embodiment of the invention. As the film configuration of the TMR element, any of various configurations can be adopted. By way of example, the TMR element is configured in such a way that, as shown in FIG. 1, a lower shield layer 10, an underlayer 12, an anti-ferromagnetic layer 13, a pinned magnetic layer 14, a barrier layer 20, a free magnetic layer 17, a cap layer 18 and an upper shield layer 19 are stacked on a substrate 7 in the order mentioned. Incidentally, a “TMR film” in this embodiment means a stacked film from the underlayer 12 to the cap layer 18.

The lower shield layer 10 is made of NiFe, which is a soft magnetic material, and it is formed by plating or sputtering. This lower shield layer 10 serves also as the electrode of the TMR element. Incidentally, methods for forming the individual layers to be described below are all based on sputtering unless otherwise specified. However, they are not restricted to sputtering.

The underlayer 12 is under the anti-ferromagnetic layer 13 made of an Mn-based anti-ferromagnetic material, and it is made of a double-layer film of Ta/Ru.

By way of example, the anti-ferromagnetic layer 13 is formed to a thickness of about 7 nm by using IrMn. Incidentally, the anti-ferromagnetic layer 13 acts to pin the magnetization direction of the pinned magnetic layer 14 by an exchange coupling action.

A ferromagnetic material such as CoFe or CoFeB is used for the pinned magnetic layer 14, and this layer 14 is formed to a thickness of about 5 nm by way of example.

A double-layer film of CoFe/NiFe is used for the free magnetic layer 17. The free magnetic layer 17 has its magnetization direction changed by a magnetization signal from a medium, and it causes the action of reading out a recorded signal, by reading its resistance change based on the fact that a relative angle to the magnetization direction of the pinned magnetic layer 14 changes at the change of the magnetization direction of this free magnetic layer 17.

The cap layer 18 is disposed as a protective layer, and it is made of a double-layer film of Ta/Ru.

Like the lower shield layer 10, the upper shield layer 19 is made of soft magnetic material such as NiFe. This upper shield layer 19 serves also as the electrode of the TMR element.

The barrier layer 20 is interposed between the pinned magnetic layer 14 and the free magnetic layer 17. In general, the barrier layer 20 is made of alumina or MgO. This barrier layer 20 passes a sense current on the basis of a tunnel effect, and it is formed to a very small thickness of about 1 nm by way of example.

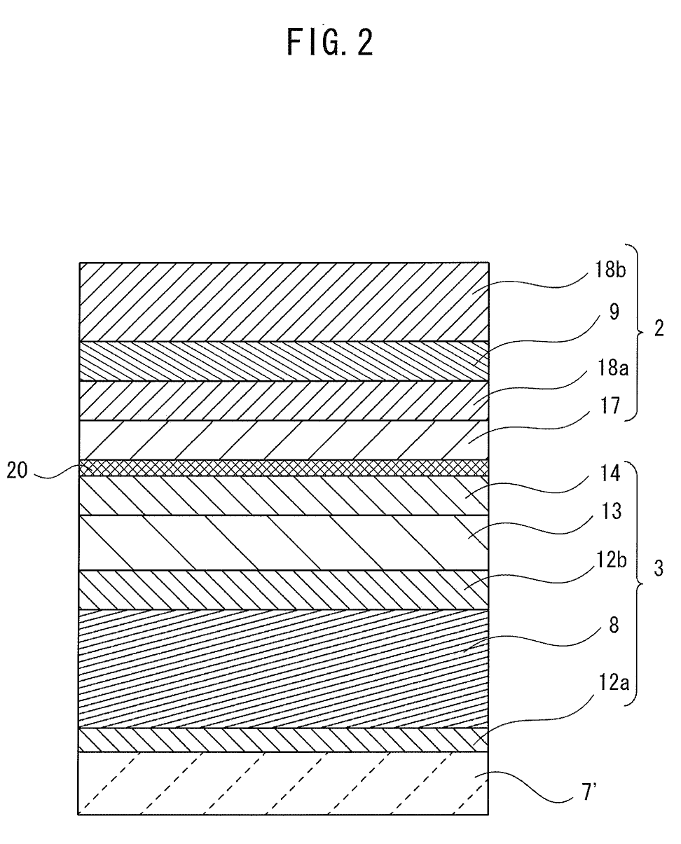

By the way, in a TMR element for a CIPT measurement as shown in FIG. 2, conductive layers are inserted in order to lower the sheet resistivities of the layers located above the barrier layer 20 (an upper-barrier layer to be described later) and the layers located below the barrier layer 20 (a lower-barrier layer to be described later). Concretely, the first conductive layer 8 is interposed between a first underlayer 12a and a second underlayer 12b under the anti-ferromagnetic layer 13. Besides, the second conductive layer 9 is interposed between a first cap layer 18a and a second cap layer 18b over the free magnetic layer 17. By way of example, each of the conductive layers 8 and 9 is made of Cu. These layers are shown on, a substrate 7′ for an experiment.

In this embodiment, regarding the TMR element for the CIPT measurement as shown in FIG. 2, the free magnetic layer 17, the first cap layer 18a, the second conductive layer 9 and the second cap layer 18b are called the “upper-barrier layer 2”, while the first underlayer 12a, the first conductive layer 8, the second underlayer 12b, the anti-ferromagnetic layer 13 and the pinned magnetic layer 14 are called the “lower-barrier layer 3”.

Here, regarding a method for measuring the sheet resistance of the magneto-resistance effect element, according to this embodiment, terms are used as stated below.

The sheet resistivity of the upper-barrier layer 2 of the magneto-resistance effect element is called the “first sheet resistivity”, which is denoted by “Rt”. The sheet resistivity of the lower-barrier layer 3 of the magneto-resistance effect element is called the “second sheet resistivity”, which is denoted by “Rb”. The units of both of the sheet resistivities Rt and Rb are “Ω” in the SI unit system, but a unit “Ω/square” is commonly used.

Incidentally, the sheet resistivity of the single layer film of the upper-barrier layer 2 formed for the measurement is denoted by “Rto”, and the sheet resistivity of the single layer film of the lower-barrier layer 3 similarly formed for the measurement is denoted by “Rbo”. Both units of the sheet resistivities Rto and Rbo are “Ω” in the SI unit system, but the unit “Ω/square” is commonly used.

Here, the ratio of the sheet resistivity Rb to the sheet resistivity Rt is denoted by “α”. That is, α=Rb/Rt holds. Incidentally, the unit of the ratio α is dimensionless.

Besides, the parallel resultant sheet resistivity of the sheet resistivities Rt and Rb is denoted by “Rs”. The unit of the resultant sheet resistivity Rs is “Ω” in the SI unit system, but the unit “Ω/square” is commonly used.

A resistance in the case where a current is caused to flow in a direction perpendicular to the plane of the TMR film in the magneto-resistance effect element is called the “area resistance of the magneto-resistance effect element”, which is denoted by “RA”. The unit of the area resistance RA is [Ω·m²] in the SI unit system.

By the way, in the magneto-resistance effect element, a resistance obtained by dividing a measurement voltage V [V] by a measurement current I [A] in the measurement based on the CIPT method is denoted by “R [Ω]”.

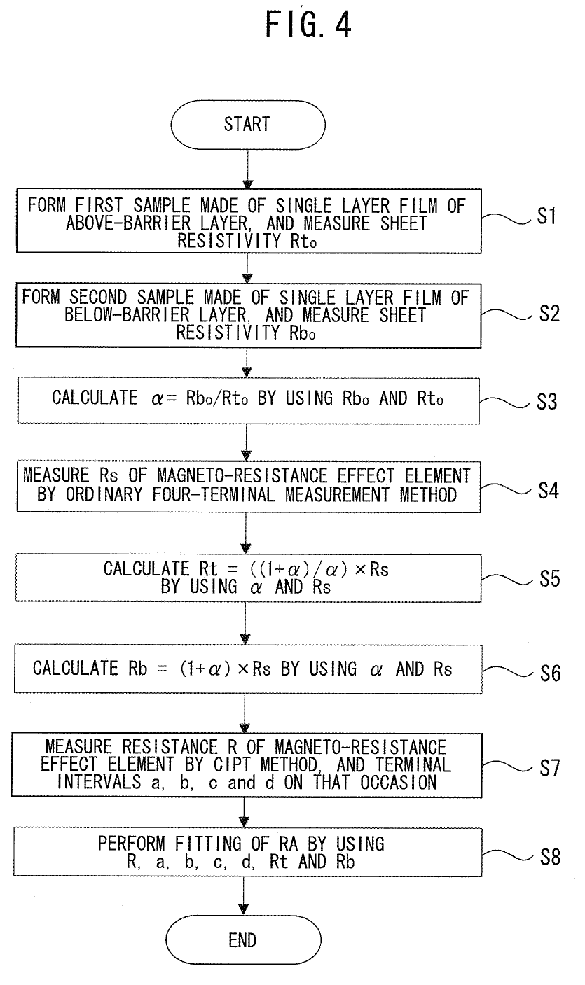

Next, the procedure of the method for measuring the area resistance of the magneto-resistance effect element, according to the first embodiment, will be described. FIG. 4 is a flow chart showing the procedure.

A first sample which only has the upper-barrier layer 2 is formed. In the first sample, resistances are measured by an ordinary four-terminal measurement method, and the sheet resistivity Rto of the film of only the upper-barrier layer 2 is calculated (step S1).

Subsequently, a second sample which only has the lower-barrier layer 3 is formed. In the second sample, resistances are measured by the ordinary four-terminal measurement method, and the sheet resistivity Rbo of the film only having the lower-barrier layer 3 is calculated (step S2).

Here, even when the film formation rate of the conductive layers 8 and 9 has fluctuated, the ratio α between the sheet resistivities of the upper-barrier layer 2 and the lower-barrier layer 3 hardly fluctuate as long as the ratio of the film formation time periods of the conductive layers 8 and 9 is constant. By utilizing this fact, the ratio α can be calculated as α=Rb/Rt≈Rbo/Rto by using the sheet resistivity Rto and the sheet resistivity Rbo (step S3).

Subsequently, the parallel resultant sheet resistivity Rs of the magneto-resistance effect element is measured. The measurement is performed by the ordinary four-terminal measurement method, but the TMR element for the CIPT measurement as shown in FIG. 2 is used for the measurement (step S4).

Subsequently, the first sheet resistivity Rt can be calculated as Rt=((1+α)/α)×Rs by using the ratio α and the resultant sheet resistivity Rs (step S5).

Besides, the second sheet resistivity Rb can be calculated as Rb=(1+α)×Rs by using the ratio α and the resultant sheet resistivity Rs (step S6).

Incidentally, the value of the ratio α does not fluctuate as long as the stack structure of the magneto-resistance element is not altered. Accordingly, once the ratio α has been obtained, the first sheet resistivity Rt and the second sheet resistivity Rb can be calculated on each occasion in conformity with the above formulas by using the obtained value. More specifically, in mass productions and experiments, TMR films having upper-barrier layers and lower-barrier layers of similar structures are formed in most cases. Therefore, it suffices to carry out the steps S1-S3 once. The steps of the step S4, et seq. may be carried out for the TMR film which is thereafter formed.

Subsequently, the resistance R of the whole magneto-resistance effect element is measured by the CIPT method. On this occasion, using the TMR element as shown in FIG. 2, the measurement is performed a plurality of times by combinations of a plurality of sorts of terminal intervals (step S7).

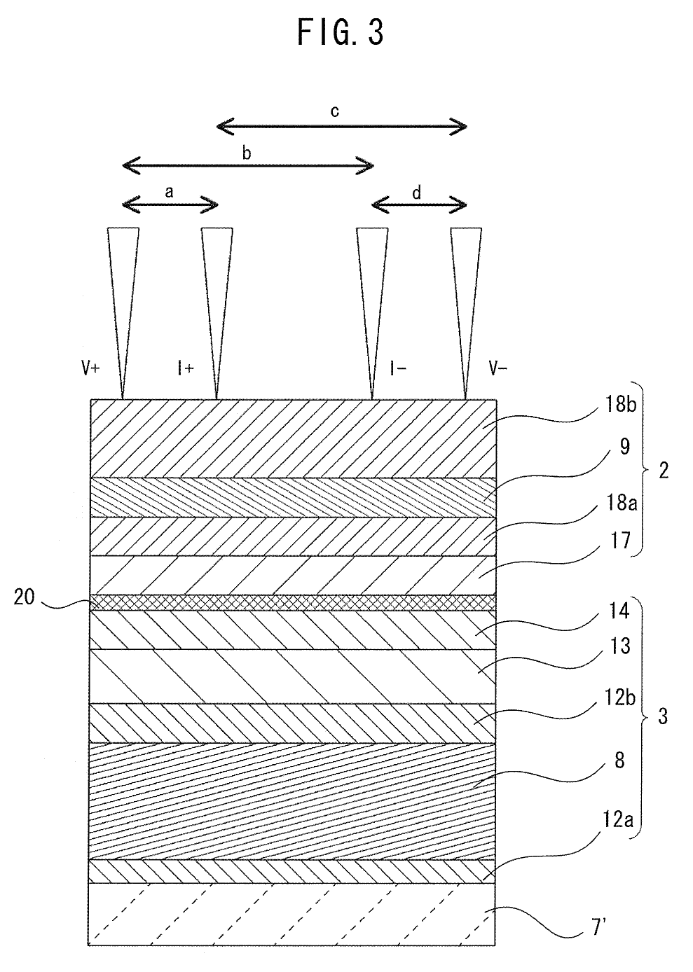

Here, as shown in FIG. 3, “a” denotes the distance between a current electrode (+) and a voltage electrode (+), “b” denotes the distance between the voltage electrode (+) and a current electrode (−), “c” denotes the distance between the current electrode (+) and a voltage electrode (−), and “d” denotes the distance between the voltage electrode (−) and the current electrode (−). All the units of the distances a, b, c and d are [m] in the SI unit system, but in this embodiment, the measurements are performed by setting the distances between the adjacent terminals to be about several μm.

The area resistance RA of the magneto-resistance effect element is fitted using the resistance R, the terminal intervals a, b, c and d, the first sheet resistivity Rt and the second sheet resistivity Rb acquired in the above ways (step S8).

Here, the establishing is performed in conformity with the following expression (1).

$$R = \frac{{R}_{t} {R}_{b}}{{R}_{t} + {R}_{b}} \frac{1}{2 π} \{ \frac{{R}_{t}}{{R}_{b}} [ {K}_{0} ( \frac{a}{λ} ) + {K}_{0} ( \frac{d}{λ} ) - {K}_{0} ( \frac{b}{λ} ) - {K}_{0} ( \frac{c}{λ} ) ] + ln ( \frac{bc}{ad} ) \} \qquad ( 1 )$$

Here, K₀ is second modified Bessel function and λ can be written as the following expression (2).

$$λ = \sqrt{\frac{RA}{{R}_{t} + {R}_{b}}} \qquad ( 2 )$$

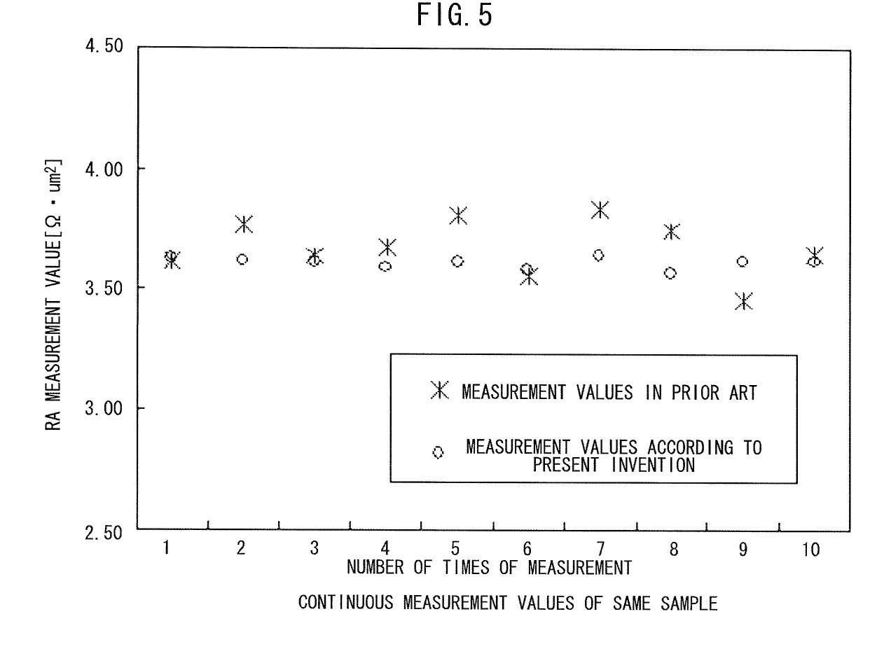

Here, the continuous measurements of the same sample were performed by the above method. The measurement results of the area resistance RA are shown in FIG. 5. Since the sample is the same, it is ideal that the measurement values (RA) do not fluctuate depending upon the number of measurements. The measurement values (RA) based on the measurement method according to this embodiment are smaller in the dispersion of numerical values as compared with measurement values (RA) based on the prior-art method, also shown in FIG. 5. It is accordingly understood that a measurement precision has been enhanced in this embodiment.

As described above, with the prior-art establishing, the three variables Rt, Rb and RA have been used, and hence, the measurement precision is inferior as compared with the dispersion of the area resistance RA, so that only a value of low reliability has been obtained.

In contrast, in the method for measuring the area resistance of the magneto-resistance effect element according to this embodiment, the sheet resistivities Rt and Rb are previously evaluated by different methods, and the values are fixed, whereby the CIPT method becomes applicable as the establishing with one variable of the area resistance RA. As a result, in the prior-art case of the three variables, the establishing has been impossible unless the resistances R are independently measured, at least, three times, whereas in this embodiment, the establishing becomes possible by measuring the resistance R, at least, once. More specifically, the resistances R are usually measured a plurality of number of times in the CIPT method in order to enhance the establishing precision. Here, when this embodiment is compared with the prior art at the same number of times of measurements, it involves one variable in opposition to the three variables in the prior art and can therefore enhance the measurement precision sharply.

Concretely, the RA measurement precision which is three times as high as that of the prior art is attained, and even a very small area resistance RA (<2 Ω·μm²) can be measured. Further, a reliable in-plane RA distribution can be acquired by measuring the area resistances RA at multiple points within a wafer.

Next, a method for measuring the sheet resistance of a magneto-resistance effect element, according to the second embodiment, will be described.

“Db” denotes the thickness of a first conductive layer 8, and “Dt” denotes the thickness of a second conductive layer 9. The ratio α between the sheet resistivities of an upper-barrier layer and a lower-barrier layer does not fluctuate even when the film formation rate of the respective conductive layers 8 and 9 has fluctuated. By utilizing this fact, the ratio α can be calculated as α=Rb/Rt≈Rbo/Rto≈Db/Dt by using the thickness ratio between the respective conductive layers 8 and 9.

Incidentally, both the units of the thicknesses Db and Dt are [m] in the SI unit system, but the thicknesses are on the order of several nm in this embodiment.

Next, a method for measuring the sheet resistance of a magneto-resistance effect element, according to the third embodiment, will be described.

The third embodiment is the same as in the first embodiment in that establishing is performed after a first sheet resistivity Rt and a second sheet resistivity Rb have been obtained beforehand. In the third embodiment, however, each of the sheet resistivities Rt and Rb is acquired by performing the prior-art CIPT method a plurality of times (several tens times-several hundred times) and calculating the average value of obtained values.

As described above, in accordance with the method for measuring the area resistance of the magneto-resistance effect element, according to this embodiment, the establishing with one variable becomes possible, whereby a measurement value (RA value) of high precision can be easily acquired. As a result, the characteristics of a TMR film can be evaluated with high precision on the basis of the RA value. Further, it is permitted to realize a manufacturing method in which the characteristics of the TMR film in a magnetic head, an MRAM or the like are immediately evaluated, and in which the evaluated characteristics are fed back to the film formation conditions of a manufacturing process.

In accordance with the method for measuring the area resistance of the magneto-resistance effect element, according to this embodiment, the first sheet resistivity Rt and the second sheet resistivity Rb are acquired beforehand, whereby the establishing with one variable being the area resistance RA of the magneto-resistance effect element becomes possible. As a result, the area resistance RA can be obtained with high precision.

Besides, the resultant sheet resistivity Rs of the magneto-resistance effect element and the ratio α of the second sheet resistivity Rb to the first sheet resistivity Rt are acquired beforehand, whereby the first sheet resistivity Rt and the second sheet resistivity Rb can be calculated.

Further, the sheet resistivity of a film formed by only an upper-barrier layer and the sheet resistivity of a film formed by only a lower-barrier layer are acquired beforehand, whereby the ratio α can be calculated. Moreover, once the ratio α has been acquired, this ratio α need not be calculated for every element formation unless the stack structure of the magneto-resistance effect element is altered greatly. Therefore, the establishing procedure of the area resistance RA can be simplified.

Still further, the ratio α can be calculated using the ratio between the thickness of a first conductive layer and the thickness of a second conductive layer.

Yet further, the sheet resistivities Rt and Rb are measured a plurality of times by the prior-art CIPT method, and the averages of measured values are calculated, whereby the sheet resistivities Rt and Rb can be calculated.

The order in which the embodiments have been described does not indicate superiority and inferiority of one embodiment over another. Although the embodiments of the present inventions have been described in detail, it should be understood that the various changes, substitutions, and alterations could be made hereto without departing from the spirit and scope of the invention.

What is claimed is:

1. A method for measuring an area resistance of a magneto-resistance effect element which includes an upper-barrier layer having a first sheet resistivity Rt, a barrier layer, and a lower-barrier layer having a second sheet resistivity Rb, comprising the steps of:
a resistance measurement step of measuring a resistance resistance R of the magneto-resistance effect element by using predetermined terminals;
a sheet resistivity measurement step of measuring the first sheet resistivity Rt and the second sheet resistivity Rb; and
a establishing step of establishing the area resistance RA of the magneto-resistance effect element by using said first sheet resistivity Rt, said second sheet resistivity Rb, said resistance R and the intervals among said predetermined terminals.

2. The method for measuring an area resistance of a magneto-resistance effect element according to claim 1,
wherein said sheet resistivity measurement step comprises:
calculating a ratio α of the second sheet resistivity Rb to the first sheet resistivity Rt;
measuring a parallel resultant resistance Rs of the sheet resistivities Rt and Rb in the magneto-resistance effect element, by a four-terminal measurement method; and
calculating the first sheet resistivity Rt and the second sheet resistivity Rb as Rt=((1+α)/α)×Rs and Rb=(1+α)×Rs, respectively, by using the ratio α and the parallel resultant resistance Rs.

3. The method for measuring an area resistance of a magneto-resistance effect element according to claim 2,
wherein said step of calculating the ratio α comprises:
the step of forming a first film having only an upper-barrier layer and a second film having only a lower-barrier layer, respectively;
the step of measuring a sheet resistivity Rto of the first film and a sheet resistivity Rbo of the second film by the four-terminal measurement method, respectively; and
the step of calculating the ratio α as α=Rbo/Rto.

4. The method for measuring an area resistance of a magneto-resistance effect element according to claim 2,
wherein the magneto-resistance effect element includes a first underlayer and a second underlayer between which a first conductive layer is interposed, and a first cap layer and a second cap layer between which a second conductive layer is interposed; and
said step of calculating the ratio α is the step of calculating the ratio α as α=Db/Dt by using a thickness Db of the first conductive layer and a thickness Dt of the second conductive layer.

5. The method for measuring an area resistance of a magneto-resistance effect element according to claim 1,
wherein said sheet resistivity measurement step comprises:
the step of measuring the resistance R in the magneto-resistance effect element, a plurality of number of times by a CIPT method;
the step of establishing the first sheet resistivity Rt and the second sheet resistivity Rb by using the resistance R; and
the step of calculating the average values measured a plurality of number of times, as the first sheet resistivity Rt and the second sheet resistivity Rb.
